(19) United States
(12) Patent Application Publication
(10) Pub. No.: US 2006/0131658 A1
(43) Pub. Date: Jun. 22, 2006

(54) MOS device, CMOS device, and fabricating method thereof

(75) Inventor: Shin Eun Jong, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/313,649

(22) Filed: Dec. 22, 2005

(30) Foreign Application Priority Data
Dec. 22, 2004 (KR) 10-2004-0110117

(51) Int. Cl. H01L 29/94

(52) U.S. Cl. 257/369

(57) ABSTRACT

A MOS or CMOS device includes a substrate with an active area, a gate oxide layer on the substrate, a gate on the gate oxide layer, first sidewalls on sides of the gate, the first sidewalls contacting the gate oxide layer, spacers formed outside the second sidewalls, and a salicide layer formed by depositing a metal layer on the gate and the active area of the substrate and annealing the deposited metal layer.

### CROSS-REFERENCE TO RELATED APPLICATIONS

This application claims the benefit of Korean Application No. 10-2004-0110117, filed on Dec. 22, 2004, which is hereby incorporated by reference as if fully set forth herein.

### BACKGROUND OF THE INVENTION

1. Field of the Invention

The present invention relates to a metal oxide semiconductor (MOS) device, a complementary MOS (CMOS) device, and a fabricating method thereof, and more particularly to, a MOS device using a damascene gate structure, and a salicide process method for a CMOS device.

2. Description of the Related Art

Nickel (Ni), titanium (Ti), and cobalt (Co) are commonly used in a salicide process of a related art MOS or CMOS device. In a CMOS device with a 0.25-μm design rule or more, Ti-salicide having a low Si consumption and low resistance characteristic is perhaps most commonly used.

On the contrary, in a high-tech, fine CMOS device with a 0.25-μm design rule or less (e.g., a gate width of ≦0.25-μm), Ti-salicide may not be used because of its narrow width effect and problems that may result from a high-temperature silicidation process. Instead, Co-salicide is widely used.

FIG. 1 is a sectional view of a related art MOS device to which a Co-salicide process is applied. Referring to FIG. 1, a gate oxide layer 40 is formed on a P-type substrate 10, and a gate 50 is formed on the gate oxide layer 40. Spacers 60 are formed on sidewalls of the gate 50. Phosphorus (P) is doped (e.g., implanted) into the substrate 10 to form a source 30 and a drain 20.

For forming a Co-salicide, an interface of the gate 50 and the active area (e.g., the regions where source 30 and drain 20 are formed) is cleaned using a diluted HF (HF:H₂O=1:100), and a Co layer is deposited (e.g., to a thicknesses of 150 Å). Next, the substrate 10 where the Co layer is deposited is annealed at 480-490° C. for 60 seconds through a rapid thermal process (RTP).

Next, a wet etching is performed using a wet etching solution containing aqueous H₂SO₄ and H₂O₂ mixed in a 1:2 ratio so as to remove cobalt (Co) metal remaining on the oxide interface. This process is sometimes known as self-aligned silicidation, and the resulting layer of material is sometimes called self-aligned silicide or “salicide.”

Then, in order to minimize a specific resistance of the Co-salicide and minimize a junction leakage, a Ti layer and a TiN layer may be deposited (e.g., to thicknesses of 200 Å and 220 Å, respectively, and usually after depositing a “pre-metal” dielectric layer and forming contact or via holes therein), and an RTP is performed at 800-820° C. for 30 seconds, thereby forming an optimized Co-salicide layer 80.

However, compared with Ti-salicide, Co-salicide has a larger Si consumption (e.g., under the same RTP conditions), and a thickness of salicide may increase as a result. Therefore, the drain-source and the gate may be shorted (a phenomenon known as “spiking”), causing much junction leakage. Also, Co-salicide (CoSi₂) has a higher specific resistance than Ti-salicide (TiSi₂).

Further, when aluminum (Al) is deposited for forming a contact, Co-salicide (CoSi₂) can react with aluminum. In order to solve this problem, a diffusion barrier layer (Ti, W, TiN, etc.) has to be further formed.

### SUMMARY OF THE INVENTION

Accordingly, the present invention is directed to a MOS device, a CMOS device, and a fabrication method thereof that substantially obviate one or more problems due to limitations and disadvantages of the related art.

An object of the present invention is to provide a MOS device, a CMOS device, and a fabricating method thereof, that may employ Ti-salicide (TiSi₂) having a low specific resistance and no reactivity with a subsequently formed contact, thereby preventing a junction leakage.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure(s) and/or process(es) particularly pointed out in the written description and claims hereof as well as the appended drawings.

To achieve these objects and other advantages and in accordance with the purpose of the invention, as embodied and broadly described herein, there is provided a MOS device including: a substrate with an active area; a gate oxide layer on the substrate; a gate on the gate oxide layer; first sidewalls on sides of the gate, the first sidewalls contacting the gate oxide layer and sides of the gate; spacers outside the first sidewalls; and a salicide layer on the gate and the active area of the substrate.

According to another aspect of the present invention, there is provided a CMOS device including an NMOS element and a PMOS element, each of the NMOS element and the PMOS element including the inventive MOS device described herein.

According to a further aspect of the present invention, there is provided a method of fabricating a CMOS device, including: patterning a first insulating layer on a substrate to thereby expose an area of a substrate; forming a gate insulating layer on the exposed area of the substrate; depositing a gate material on the gate insulating layer and planarizing the deposited gate material; patterning at least the gate material and the first insulating layer at a predetermined width to thereby form a gate and first sidewalls; forming spacers from a second insulating layer deposited on the substrate and the gate; forming source and drain regions by implanting first impurity ions into the substrate adjacent to the spacers; depositing a metal layer on the gate and the substrate; and annealing the metal layer to form a salicide.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a cross-sectional view of a MOS device to which a related art Co-salicide process is applied;

FIG. 2 is a cross-sectional view of an NMOS device including a salicide according to a first embodiment of the present invention;

FIGS. 3 to 7 are cross-sectional views illustrating a method of fabricating the NMOS device to which the salicide process is applied according to the first embodiment of the present invention;

FIG. 8 is a cross-sectional view of a PMOS device including a salicide according to a second embodiment of the present invention;

FIG. 9 is a cross-sectional view of a CMOS device including a salicide according to a third embodiment of the present invention; and

FIG. 10 is a cross-sectional view of a twin well CMOS device including a salicide process according to a fourth embodiment of the present invention.

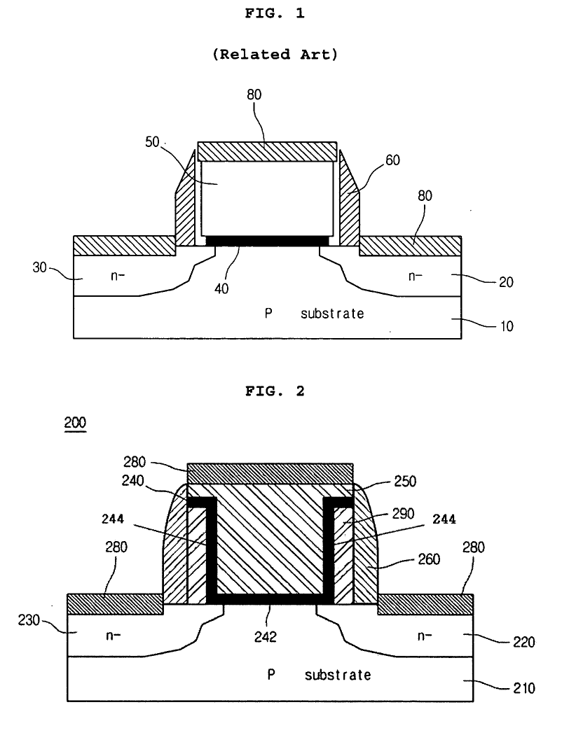

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a MOS device, a CMOS device, and a fabricating method thereof according to the embodiments of the present invention will be described in detail with accompanying drawings. The fabricating method and effect of the MOS device according to the present invention can also be applied to those of the CMOS device.

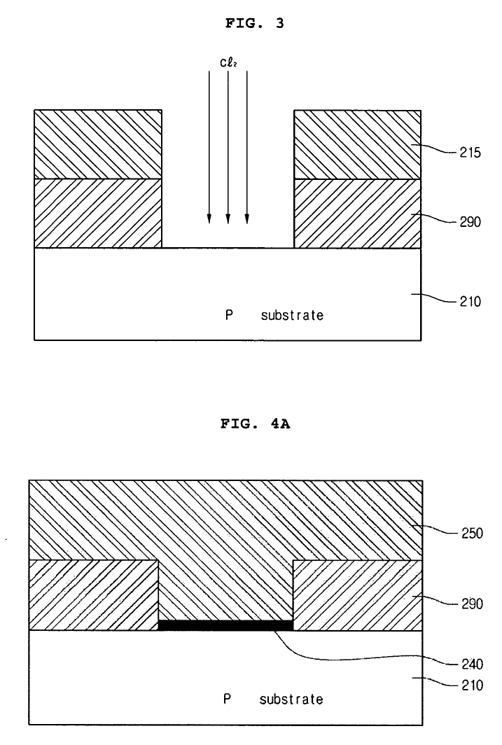

FIG. 2 is a cross-sectional view of an NMOS device 200 including a salicide (e.g., Ti-salicide) according to a first embodiment of the present invention.

Referring to FIG. 2, the MOS device 200 includes a substrate 210 with an active area (including source and drain regions 220 and 230), a gate oxide layer 242 on the substrate 210, a gate 250 on the gate oxide layer 242, (optional) sidewalls 244 on sides of the gate 250, the sidewalls 244 comprising the same material as and being unitary with the gate oxide layer 242, sidewalls 290 outside the optional sidewalls 244 (e.g., contacting a surface of the optional sidewalls 244 opposite the surface of the optional sidewalls 244 that contacts the gate 250), spacers 260 outside the sidewalls 290, and a salicide layer 280. The salicide layer 280 may be formed by depositing a metal layer on the gate 250 and the active area of the substrate 210, and then annealing the deposited metal layer.

The gate oxide layer 242 and the optional sidewalls 244 may be simultaneously formed of the same material, by conformally depositing an insulator material (such as silicon dioxide, silicon nitride, etc.) onto a patterned precursor structure (discussed below with regard to FIG. 4B) and annealing to densify the insulator material. The gate oxide layer 242 and the first sidewalls 244 may thus form a unitary gate insulating layer 240. In the gate insulating layer 240, a portion in contact with the substrate 210 may be referred to as the gate oxide layer 242, and the remaining portion (or at least the vertical portion thereof) may be referred to as the sidewall(s) 244.

Alternatively, the gate oxide layer 242 may be formed on the substrate (i.e., not on sidewalls 290) by conventional wet or dry thermal oxidation. In one embodiment, the gate oxide layer 242 may comprise first and second gate oxides (not shown in FIG. 2), formed by a dual oxidation process. The gate oxide 242 can have a thickness in a first device of 30-60 Å (preferably 45-55 Å) and a thickness in a second device of 15-40 Å (preferably 20-30 Å) through a dual oxidation process using rapid thermal processing (RTP). In such a dual oxidation process, the substrate may be doped differently in the first and second devices, and the different doping (e.g., dopant types and/or doses) may give rise to differential growth rates of the gate oxide in the first and second devices. To obtain greater differences in gate oxide thicknesses, the gate oxide(s) may be etched back (at substantially the same rate) using wet etching (e.g., dilute aq. HF or a conventional buffered oxide etch solution) and re-grown until the desired thicknesses are achieved. Alternatively, the different gate oxides can be grown or deposited one at a time, with the first gate oxide being formed for a subset of devices while the remaining devices are masked, then the device areas including the first gate oxide are masked while the second gate oxide is formed in another subset of devices. In one implementation of this embodiment, the gate insulating layer 240 may have a first thickness of about 50 Å and a second thickness of about 25 Å.

Also, the sidewalls 290 can be formed by depositing a (partially) sacrificial layer having a thickness of 1900-2200 Å through a low pressure chemical vapor deposition (LP-CVD). The (partially) sacrificial layer can comprise a tetraethylorthosilicate (TEOS)-based oxide. In this embodiment, the TEOS layer may have a thickness of 2000-2100 Å as deposited.

Also, the gate 250 can be formed by depositing polysilicon to a thickness of 4500-6000 Å. In one embodiment, the polysilicon has a thickness of 5000-5500 Å.

In addition, the spacers 260 are formed by a conventional spacer forming process. Further, the source 230 and the drain 220 (or vice versa) are formed by doping (e.g:, implanting) ions of a group V element (e.g., P, As and/or Sb) after the spacers 260 are formed. For a PMOS device, ions of a group III element (e.g., B) are implanted.

Moreover, the salicide layer 280 is formed by depositing a metal layer on the gate 250 and the active area of the substrate 210 and annealing the deposited metal layer. The metal layer can be formed by depositing Ti to a thickness of 300-400 Å. Although Ti is the preferred metal for forming salicide in this invention, cobalt (Co) and nickel (Ni) salicides are also contemplated. TiN may be subsequently deposited on the salicide at a thickness of 100-200 Å, either directly by CVD from an organometallic TiN precursor or by PVD deposition (e.g., sputtering) of Ti, alone or in the presence of a nitridizing agent (e.g., nitrogen gas or ammonia), and/or with subsequent annealing in a nitridizing atmosphere (e.g., containing nitrogen gas or ammonia). In one implementation of this embodiment, Ti and TiN may have thicknesses of about 340 Å and about 150 Å, respectively.

The MOS device and the CMOS device according to the present invention may include a damascene gate structure and a Ti salicide layer. A significant difference from the related art Co-salicide will be described below in detail.

According to an experimental example, when the related art Co-salicide process is applied in a CMOS device having design rules of 0.25-μm or less, a 3.52-Å Co-salicide (CoSi₂) layer may be formed by a 1-Å layer of cobalt. The corresponding Si consumption is about 3.64 Å.

On the contrary, when the Ti-salicide process is applied, a 2.51-Å Ti-salicide (TiSi₂) layer may be formed by a 1-Å layer of titanium. The corresponding Si consumption is about 2.27 Å.

Therefore, compared with Ti-salicide, Co-salicide has a large Si consumption, and its thickness is generally larger. Consequently, the drain-source terminals may be shorted to the substrate, causing relatively high junction leakage.

However, the MOS device and the CMOS device according to the present invention can solve these problems. As the thickness of salicide decreases, a mechanical compression force decreases. Therefore, movement or consumption of Si for forming the salicide is reduced (e.g., during a thermal treatment for forming the salicide). Consequently, a rough surface is not formed, and problems that may result from an increase of a leakage current and contact resistance may be solved, reduced and/or avoided.

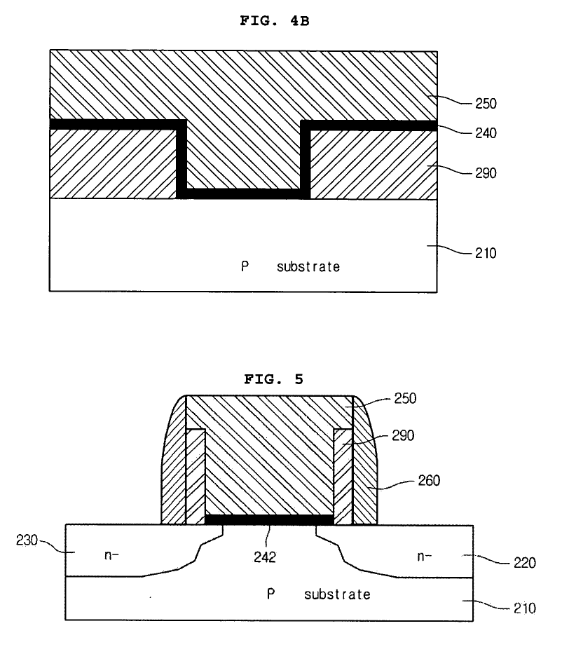

A fabricating method of the NMOS device to which a salicide process is applied according to an embodiment of the present invention will be described below in detail with reference to FIGS. 3 to 7.

The method of fabricating a device according to an embodiment of the present invention includes: patterning a first insulating layer on a substrate to thereby expose an area of the substrate; forming a gate insulating layer on the substrate; depositing a gate material on the gate insulating layer and planarizing the deposited gate material; patterning the gate material and the first insulating layer at a predetermined width to thereby form a gate and first sidewalls; forming spacers from a second insulating layer; forming source and drain regions by implanting first impurity ions into the substrate adjacent to the spacers; depositing a metal layer on the gate and the substrate; and annealing the metal layer to form a salicide.

The process of forming the gate will be described below with reference to FIGS. 3 and 4.

Referring to FIG. 3, a first insulating layer 290 is deposited on a semiconductor substrate 210. The first insulating layer 290 can be formed by depositing an insulator layer (e.g., a TEOS- or silane-based oxide having a thickness of, e.g., 1900-2200 Å) by CVD (e.g., a low pressure chemical vapor deposition, or LP-CVD). Then, to form the gate on the substrate 210 where the first insulating layer 290 is deposited, a pattern or trench is formed in insulating layer 290 by conventional photolithographic patterning using a photoresist layer 215 and dry-etching the first insulating layer 290 (e.g., using Cl₂ gas or other conventional oxide etchant).

Referring to FIG. 4A, a gate insulating layer 240 (that may comprise a dual gate oxide) may be formed (e.g., by conventional oxidation or a dual oxidation process) using a RTP. Alternatively, as shown in FIG; 4B, the gate insulating layer 240 may be formed by conformal deposition (e.g., CVD) of, e.g., a TEOS- or silane-based oxide.

Polysilicon as a gate material 250 is deposited on the gate insulating layer 240 and (generally) on the first insulating layer 290 to a thickness, e.g., of 4500-6000 Å. Then, the gate material 250 is planarized using a conventional plasma etchback technique or chemical mechanical polishing such that a relatively thin layer of the gate material 250 (e.g., about 400-600 Å) remains on the first insulating layer 290. In this embodiment, the gate material 250 may be deposited to a thickness of 5000-5500 Å, and then be planarized to a thickness of about 500 Å on the first insulating layer 290.

Referring to FIG. 5, for a gate patterning, a photolithography process and a dry etching process are performed to remove parts of the gate material 250, the gate insulating layer 240 (when present on the upper surface of the first insulating layer 290), and the first insulating layer 290, thereby forming a gate 250 (on gate oxide 242) and at least sidewalls 290, the combined structure having a predetermined width. However, as is clear from FIG. 5, the gate in the present MOS device may comprise an upper portion having a first width and a lower portion having a second width, the first width being greater than the second width.

Then, a lightly doped drain (LDD) region (not marked) is formed by implanting first impurity ions into the substrate 210 adjacent to the sidewalls 290. After forming the LDD region, a second insulating layer (not shown) is formed using a general process (such as blanket and/or conformal deposition) and is anisotropically etched (e.g., by dry etching) to form spacers 260. Source and drain regions 220 and 230 are formed by implanting second impurity ions (which may be the same as or different from the first impurity ions, but which are the same type [e.g., N-type or P-type]) into the substrate 210 adjacent to the spacers 260. Thereafter, a Pre-Amorphization Implant (PAI) process may be performed to form a transistor.

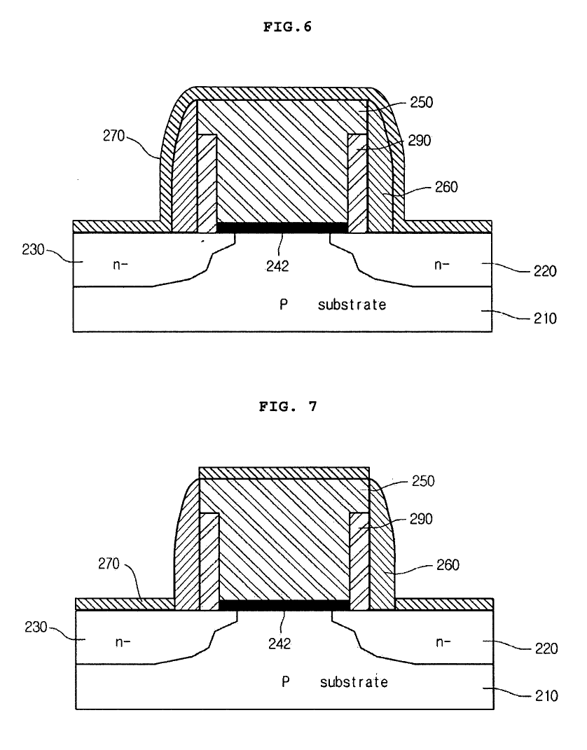

Referring to FIG. 6, for forming a salicide, the gate 250 and the active area of the substrate 210 are cleaned using a dilute hydrofluoric acid (DHF) in which a HF:H₂O ratio is from about 1:90 to about 1:110. In one implementation of this embodiment, the cleaning process is performed using DHF in which the HF:H₂O ratio is about 1:100.

After the cleaning process, Ti and TiN can be deposited as a metal layer 270 to thicknesses of 300-400 Å and 100-200 Å, respectively. In this embodiment, Ti and TiN are deposited to 340 Å and 150 Å, respectively. At this time, since Ti-salicide is capped with TiN, an oxidation of Ti-salicide due to a thermal treatment can be prevented. Alternatively, TiN can be deposited after thermal processing of the Ti salicide, deposition of a pre-metal dielectric layer, optional planarization of the pre-metal dielectric layer, and patterning of the pre-metal dielectric layer to form a plurality of contact holes, each such contact hole exposing a source, drain or gate area of a MOS device.

In order to form Ti-salicide (TiSix) on the gate 250 where the metal layer 270 is deposited, a first thermal treatment that comprises an annealing process is performed in a nitrogen atmosphere by a RTP. The first thermal treatment can be performed at a temperature of 600-800° C. for a length of time of 10-50 seconds. In one implementation of this embodiment, the first thermal treatment is performed at 700-750° C. for about 30 seconds.

The reasons why the RTP is performed in the nitrogen atmosphere are as follows. First, it is possible to prevent a drain or source and the gate from being shorted due to the diffusion of titanium toward silicon during the salicide process. Second, since nitrogen is absorbed into a Ti grain boundary, it can react with Ti to form TiN and thus act as a diffusion barrier layer, so that it obstructs or inhibits the movement of silicon atoms from the active area into overlying contact metallization. Therefore, Ti-salicide (TiSi₂) is not formed on the spacers, thereby preventing the shorting.

Referring to FIG. 7, the metal layer, and not the salicide, remaining at the interface with the oxide material is removed through a self-aligned silicidation, except an upper region on the gate comprising Ti-salicide (TiSix). At this time, the metal layer can be removed by a wet etching process using a wet etching solution in which H₂SO₄ and H₂O₂ (which may both be concentrated aqueous solutions) are mixed in a ratio (by volume or weight) of from about 1:1 to about 1:3. In one implementation of this embodiment, H₂SO₄ and H₂O₂ are mixed in a ratio (by volume or weight) of about 1:2. Also, NH₄OH:H₂O (preferably deionized water, or DIW) :30%H₂O₂=1:1-2:4-6 can be used as the wet etching solution.

After removing the metal layer remaining at the interface of the oxide material, a second thermal treatment that comprises an annealing process may be performed at a temperature of 700-900° C. for a length of time of 10-30 seconds such that a phase shift for reducing a specific resistance of Ti-salicide results or is possible. In one implementation of this embodiment, the second thermal treatment is performed at 800-850° C. for about 20 seconds.

At this time, the second thermal treatment can be performed in Ar atmosphere. Meanwhile, when temperature of the second thermal treatment exceeds 900° C., atoms at the drain or source are rapidly diffused into the salicide layer disposed above the drain or source. Consequently, the contact resistance may increase. Therefore, it is preferable that the temperature of the second thermal treatment should not exceed 900° C.

Through the above processes, the NMOS device according to the first embodiment of the present invention is completed. According to this embodiment of the present invention, the damascene gate structure and the salicide (particularly Ti salicide) make it possible for the NMOS device to reduce the specific resistance of the salicide, to stabilize the contact leakage, and to have high electrical efficiency.

According to the related art, when aluminum (Al) is deposited for forming a contact, Co-salicide (CoSi₂) reacts with aluminum. In order to solve this problem, a diffusion barrier layer (Ti, W, TiN, TiW alloy, etc.) has to be further formed. On the contrary, the MOS or CMOS device according to the present invention does not require such a diffusion barrier layer.

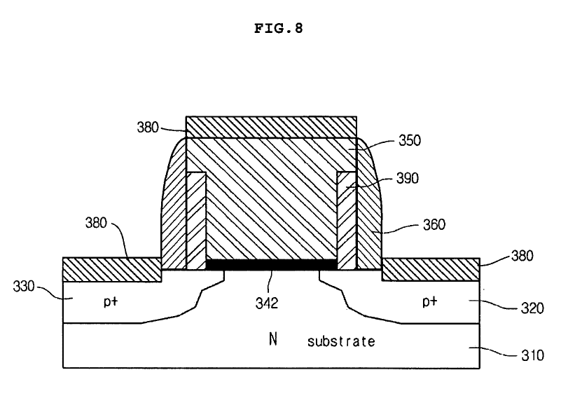

FIG. 8 is a sectional view of a PMOS device 300 including a salicide according to a second embodiment of the present invention.

Referring to FIG. 8, the PMOS device 300 includes a substrate 310 with an active area, a gate oxide layer 342 on the substrate 310, a gate 350 on the gate oxide layer 342, sidewalls 390 on the outside (and under a portion of) the gate 350, spacers 360 outside the sidewalls 390, and a salicide layer 380 formed by depositing a metal layer on the gate 350 and the active area of the substrate 310 and then annealing the deposited metal layer.

In this embodiment, the substrate 310 of the PMOS device 300 is an N-type substrate. The fabricating method according to the second embodiment of the present invention can employ the fabricating method according to the first embodiment of the present invention.

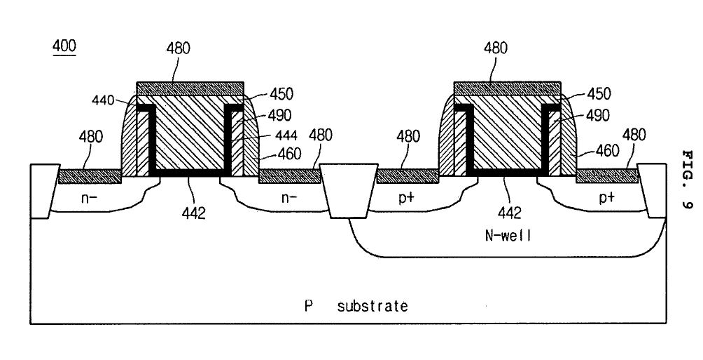

FIG. 9 is a sectional view of a CMOS device 400 including a salicide according to a fourth embodiment of the present invention. Referring to FIG. 9, the CMOS device 400 includes an N-well type CMOS device in which an NMOS element is formed in a P-type substrate and a PMOS element is formed in an N-well.

The CMOS device 400 according to the third embodiment of the present invention includes a P-type semiconductor substrate with an active area. An N-well is formed in a portion of the substrate, and a PMOS element or device is formed in the N-well. Simultaneously and/or independently, an NMOS element or device is formed in another portion of the substrate (e.g., source and drain regions of the PMOS device and the NMOS device [including LDD regions] are formed independently, but other structures may be formed simultaneously).

Each of the PMOS and NMOS elements includes a substrate 410 with an active area, a gate oxide layer 442 on the substrate 410, a gate 450 on the gate oxide layer 442, first (optional) sidewalls 444 formed on sides of the gate 450, the first sidewalls 444 being unitary with the gate oxide layer 442 and in contact with a portion of the gate 450, second sidewalls 490 outside the first (optional) sidewalls 444, spacers 460 outside the second sidewalls 490, and a salicide layer 480 on the gate 450 and the active area of the substrate 410. The salicide layer 480 may be formed by depositing and annealing a metal layer. The gate oxide layer 442 and the first sidewalls 444 may form a unitary gate insulating layer 440. In the gate insulating layer 440, a portion in contact with the substrate 410 may be referred to as the gate oxide layer 442, and the remaining portion (or at least the vertical portion thereof) may be referred to as the sidewall(s) 444.

In a method of fabricating the CMOS device 400 according to the third embodiment of the present invention, the N-well is formed by implanting ions of a group V element into a predetermined region of the P-type substrate. Also, a general CMOS fabricating method can be applied to implement the NMOS element. The present invention can also be applied to a P-well type CMOS device in which a PMOS element is formed in an N-type substrate and an NMOS element is formed in a P-well.

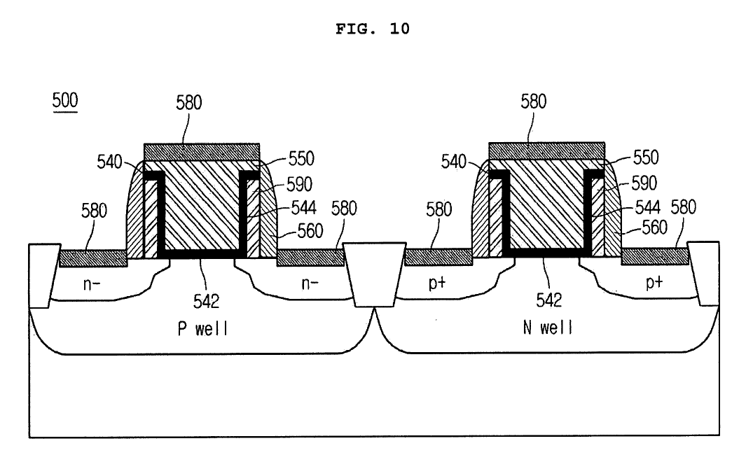

FIG. 10 is a sectional view of a twin well CMOS device 500 including a salicide (e.g., a Ti-salicide) according to a fourth embodiment of the present invention.

The twin well CMOS device 500 is a CMOS device in which a P-well is formed in a portion of a substrate and an N-well is formed in another portion of the substrate. The twin well CMOS device 500 according to the present invention comprises a CMOS device having a more optimized PMOS and NMOS performance.

In the twin well CMOS device 500 according to the fourth embodiment of the present invention, a PMOS element is implemented or located in an N-well in a portion of a semiconductor substrate (e.g., in a first active area), and simultaneously and/or independently, an NMOS element is implemented in a P-well in another portion of the semiconductor substrate (e.g., in a second active area).

Each of the PMOS and NMOS elements includes a substrate 510 with an active area, a gate oxide layer 542 on the substrate 510, a gate 550 on the gate oxide layer 542, first (optional) sidewalls 544 on sides of the gate 550, the first sidewalls 544 being unitary with the gate oxide layer 542 and in contact with a portion of the gate 550, second sidewalls 590 outside the first sidewalls 544 (and under an upper portion of the gate 550), spacers 560 outside the second sidewalls 590, and a salicide layer 580 on the gate 550 and the active area of the substrate 510 that may be formed by depositing and annealing a metal layer. The gate oxide layer 542 and the first sidewalls 544 may form a unitary gate insulating layer 540. In the gate insulating layer 540, a portion in contact with the substrate 510 may be referred to as the gate oxide layer 542, and the remaining portion (or at least the vertical portion thereof) may be referred to as the sidewall(s) 544.

According to the present invention, the damascene gate structure and the salicide (particularly the Ti salicide) make it possible for the MOS and CMOS devices to reduce the specific resistance of the salicide, to be stable in terms of contact leakage, and to have high electrical efficiency.

It will be apparent to those skilled in the art that various modifications and variations can be made in the present invention. Thus, it is intended that the present invention covers the modifications and variations of this invention provided they come within the scope of the appended claims and their equivalent.

What is claimed is:

1. A metal oxide semiconductor (MOS) device comprising:
a substrate having an active area;
a gate oxide layer on the substrate;
a gate on the gate oxide layer;
first sidewalls on sides of the gate, the first sidewalls contacting the gate oxide layer;
spacers outside the first sidewalls; and
a salicide layer on the gate and the active area of the substrate.

2. The MOS device according to claim 1, wherein the gate oxide layer includes a first gate oxide layer having a thickness of 45-55 Å and a second gate oxide layer having a thickness of 20-30 Å.

3. The MOS device according to claim 1, wherein the gate comprises polysilicon having a thickness of 4500-6000 Å.

4. The MOS device according to claim 1, wherein the salicide layer is formed by depositing a metal layer on the gate and the active area of the substrate and annealing the deposited metal layer.

5. The MOS device according to claim 4, wherein the metal layer comprises Ti having a deposited thickness of 300-400 Å.

6. The MOS device according to claim 1, wherein the gate comprises an upper portion having a first width and a lower portion having a second width, the first width being greater than the second width.

7. The MOS device according to claim 1, wherein the MOS device has a 0.25-μm design rule or less.

8. The MOS device according to claim 1, wherein the salicide layer comprises Ti silicide, and the MOS device further comprises a TiN layer on the Ti silicide, the TiN layer having a thickness of 100-200 Å.

9. A complementary metal oxide semiconductor (CMOS) device comprising an NMOS element and a PMOS element, each of the NMOS element and the PMOS element including:
a substrate having an active area;
a gate oxide layer on the substrate;
a gate on the gate oxide layer;
first sidewalls on sides of the gate, the first sidewalls contacting the gate oxide;
spacers outside the first sidewalls; and
a salicide layer on the gate and the active area of the substrate.

10. The CMOS device according to claim 9, wherein the gate comprises polysilicon having a thickness of 4500-6000 Å.

11. The CMOS device according to claim 9, wherein the salicide layer comprises Ti silicide, and the CMOS device further comprises a TiN layer on the Ti silicide, the TiN layer having a thickness of 100-200 Å.

12. The CMOS device according to claim 9, wherein the gate comprises an upper portion having a first width and a lower portion having a second width, the first width being greater than the second width.

13. The CMOS device according to claim 9, wherein the CMOS device has a 0.25-μm design rule or less.

14. A method of fabricating a complementary metal oxide semiconductor (CMOS) device, comprising:
patterning a first insulating layer on a substrate to expose a portion of the substrate;
forming a gate insulating layer on the exposed portion of the substrate;
depositing a gate material on the gate insulating layer and planarizing the deposited gate material;
patterning the gate material and the first insulating layer at a predetermined width to thereby form a gate and first sidewalls, respectively;
forming spacers from a second insulating layer on the substrate, adjacent to the first sidewalls;
forming source and drain regions by implanting first impurity ions into the substrate adjacent to the spacers;
depositing a metal layer on the gate and the substrate; and
annealing the metal layer to form a salicide.

15. The method according to claim 14, further comprising, after patterning the gate material and the first insulating layer, forming a lightly doped drain (LDD) region by implanting second impurity ions into the substrate and performing a thermal treatment.

16. The method according to claim 14, wherein forming the gate insulating layer includes forming first and second gate oxide layers having respective thicknesses of 45-55 Å and 20-30 Å through a dual or differential oxidation process.

17. The method according to claim 14, wherein depositing the gate material includes depositing a layer of polysilicon to a thickness of 4500-6000 Å.

18. The method according to claim 14, wherein depositing the metal layer comprises depositing Ti to a thickness of 300-400 Å.

19. The method according to claim 18, further comprising forming a layer of TiN having a thickness of 100-200 Å on the salicide.

20. The method according to claim 14, wherein annealing the metal layer includes:
performing a first thermal treatment on the substrate;
cleaning the substrate to remove a remaining metal layer; and
performing a second thermal treatment on the substrate.

21. The method according to claim 20, wherein the first thermal treatment comprises a rapid thermal process (RTP) performed at 600-800° C., for 10-50 seconds in a nitrogen atmosphere.

22. The method according to claim 20, wherein cleaning the substrate comprises wet etching using a solution comprising aqueous H₂SO₄ and aqueous H₂O₂ mixed in a ratio of from 1:1 to 1:3.

23. The method according to claim 20, wherein the second thermal treatment comprises annealing, performed at 700-900° C. for 10-30 seconds in a nitrogen atmosphere.
